(19) United States
(12) Patent Application Publication
(10) Pub. No.: US 2025/0377415 A1
(43) Pub. Date: Dec. 11, 2025

(54) INSTABILITY FAULT MONITORING METHOD WITH SELF-LEARNING STRONG GENERALIZATION CAPABILITY AND INSTABILITY FAULT MONITORING APPARATUS

(71) Applicant: ZHEJIANG UNIVERSITY, Hangzhou (CN)

(72) Inventors: XIN ZHANG, HANGZHOU (CN); XUEQI LIU, HANGZHOU (CN); XIAOQI ZHANG, HANGZHOU (CN); FANFAN LIN, HANGZHOU (CN); HAO MA, HANGZHOU (CN); CHUAN YAO, HANGZHOU (CN)

(73) Assignee: ZHEJIANG UNIVERSITY, (omitted)

(21) Appl. No.: 18/909,908

(22) Filed: Oct. 8, 2024

(30) Foreign Application Priority Data
Jun. 6, 2024 (CN) 202410728648.4

(51) Int. Cl. G01R 31/40

(52) U.S. Cl. CPC G01R 31/40

(57) ABSTRACT

The present invention discloses an instability fault monitoring method with self-learning strong generalization capability and an instability fault monitoring apparatus. First, electrical volume acquisition nodes are identified and data composition features are collected to form samples, the samples including a small number of labeled data samples and a large number of unlabeled data samples. Then, the samples are input into a reinforcement learning network of actor-critic architecture, and self-learning can be realized by means of the network to form different diagnostic models, where actor selects a suitable network layer from action space (alternative models) to construct a deep belief neural network and formulate a corresponding strategy, critic is configured to evaluate the strategy currently formulated by actor, and the reinforcement learning network outputs the corresponding actor-critic architecture and diagnostic model. Finally, the trained diagnostic model is used to diagnose an instability state of a power electronic system online in real time. The method is capable of simultaneously solving the problems about instability monitoring and single-module faults for different power electronic system structures and fault diagnosis tasks, and has strong generalization capability and high adaptive use.

### FIELD OF TECHNOLOGY

The present invention belongs to the technical field of instability detection for power electronic systems, and particularly relates to an instability fault monitoring method with self-learning strong generalization capability and an instability fault monitoring apparatus.

### BACKGROUND TECHNOLOGY

In complex power electronic systems, distributed energy resources (e.g., solar photovoltaic panels and wind turbines), energy storage systems (e.g., batteries), and loads are connected in a network via power electronic converters. This configuration has the advantages of improving energy utilization efficiency, reducing energy losses during transmission, and increasing system reliability. However, when the converters are cascaded with each other, even though each of the converters is stable when working independently, the converters, when combined together, may cause the problem of instability due to impedance mismatch, which in turn affects the normal operation of the power electronic systems.

Conventional instability monitoring for power electronic systems usually relies on impedance measurement-based techniques, which obtain impedance information by introducing small disturbance signals and analyzing response signals. However, this intrusive approach may negatively affect system operation and power quality. Furthermore, in the power electronic systems, not only is there a problem of instability caused by cascading of the converters, but also the independent operation of individual converters may lead to faults, and existing detection methods often fail to account for both situations.

Therefore, to address the following issues: the lack of suitable data-driven methods that may overcome the limitation of small labeled sample data; the lack of methods that may diagnose both the problem of instability caused by impedance mismatch of cascaded converters and independent instability of individual converters; and the lack of generalized state monitoring solutions for different power electronic systems or power electronic systems where the structure changes at any time because of the constant presence of load/source cut-in and cut-out,

There is a need to develop a system that may autonomously learn and generate solutions for different tasks.

Patent document CN113536607A discloses a method and system for evaluating a signal transmission system of a substation. The method includes: step S1, establishing a simulation model of the signal transmission system of the substation, and utilizing the simulation model to simulate faulty signal transmission to obtain sample data for fault evaluation; step S2, training, based on the sample data for fault evaluation, a CNN-LSTM time series forecasting model to construct a fault path prediction model for predicting a signal transmission fault path; and step S3, applying the fault path prediction model to the signal transmission system of the substation for online evaluation. The model is unable to automatically optimize parameters and has certain errors.

Patent document CN115828165A discloses a new energy smart microgrid data processing method and system. The method includes: collecting time series data of a digital intelligent energy-saving cabinet; generating features A, B and C of a derivative class based on the preprocessed time series data; inputting the preprocessed data in step S2 into an LSTM to mine temporal features related to faults of the digital intelligent energy-saving cabinet; inputting the features A, B and C of the derivative class generated in step S3 into a convolutional neural network (CNN) to mine spatial features related to the faults of the digital intelligent energy-saving cabinet, and integrating the temporal features and the spatial features; and constructing a fault classification model SVM for the digital intelligent energy-saving cabinet to realize fault classification. However, this method requires large data samples to train the model to achieve accurate fault classification.

### SUMMARY OF THE INVENTION

The present invention aims to provide an instability fault monitoring method with self-learning strong generalization capability and an instability fault monitoring apparatus. The method may self-generate suitable diagnostic models for different systems and different instability fault diagnostic tasks for accurate diagnostic localization.

In order to realize the first purpose of the present invention, the following technical solution is provided: an instability fault monitoring method with self-learning strong generalization capability includes the following steps:
step 1, collecting electrical data of each electronic device in a power electronic system, selecting some of the electrical data to be labeled with types of system instability faults, and combining the labeled electrical data with unlabeled electrical data to form dataset samples;
step 2, constructing a classification network based on a deep belief neural network framework, the classification network including a plurality of superimposed and connected network layers and a softmax layer connected to an end network layer, training the classification network using the dataset samples to construct a determination model for determining whether the power electronic system has an instability fault, and
optimizing the training process of the classification network using a reinforcement learning algorithm, where a reinforcement learning network takes a network structure composed of different numbers of network layers and a softmax layer as action space, and takes a loss rate of the determination model of previous and latter trainings as an optimization objective to obtain an optimization result, where the optimization result includes a superimposed network structure and a corresponding predicted loss rate; and
step 3, inputting the electrical data in the power electronic system into a determination model satisfying a predetermined predicted loss rate in step 2, so as to output a determination result indicating whether the power electronic system has an instability fault.

Specifically, the specific process of collecting the electrical data is as follows:
taking a bus of the power electronic system as a backbone, and regarding power converters in the system as module branches to be connected to the backbone, so as to construct an equivalent model of the power electronic system; and
collecting electrical data from each module branch and the backbone according to a predetermined type of instability faults, i.e, determining the corresponding instability fault category K to be identified, the fault problems to be solved being {stability, instability, module 1 failure, module 2 failure, . . . , module K failure}.

Specifically, the reinforcement learning algorithm is an actor-critic reinforcement learning model. Actor and critic are both multilayer perceptron structures, and the diagnostic model to be constructed is a deep belief neural network including a plurality of network layers connected in a superimposed manner as well as a softmax layer connected to an end network layer. The network layers are selected from the action space, and the output classification of the softmax layer connected to the end network layer is determined by a diagnostic task category K targeted.

Specifically, the training process includes an unsupervised pre-training phase and a supervised back-propagation fine-tuning phase;
in the pre-training phase, each of the network layers is trained using a contrastive divergence algorithm based on the dataset samples, so as to construct an initial determination model; and
in the back-propagation fine-tuning phase, the constructed initial determination model is fine-tuned based on the labeled electrical data to obtain the determination model for determining whether the power electronic system has an instability fault.

Specifically, the process of optimizing the classification network using the reinforcement learning algorithm is as follows:
step 2-1, randomly initializing an underlying network layer to obtain initial training model accuracy;
step 2-2, using a fine-tuned determination model at a current moment as a framework, and selecting an alternative network layer as a hidden layer of the network layers in the framework using a greedy algorithm to generate a determination model at a next moment;
step 2-3, comparing a predicted loss rate of the fine-tuned determination model at the current moment with a predicted loss rate of the determination model at the next moment generated in step 2-2, and placing a comparison result as a reward value and a corresponding determination model into an experience playback buffer;
step 2-4, repeating step 2-2 to step 2-3 until the total number of reward values in the experience playback buffer reaches a threshold;
step 2-5, acquiring electrical data and corresponding prediction results from the experience playback buffer as test samples, and calculating a target return value for each determination model based on the test samples; and
step 2-6, calculating corresponding losses based on the target return values, and updating parameters in the action space in a gradient descent method based on the calculated losses to output a determination model satisfying requirements.

Specifically, the expression of the reward value is as follows:

$${R}_{t} = \{ \begin{matrix}1 & if accuracy : {DBN}_{t + 1} \geq {DBN}_{t} \\ - 1 & if accuracy : {DBN}_{t + 1} < {DBN}_{t}\end{matrix}$$

where DBNₜ₊₁ denotes the determination model at the next moment, and DBNₜ denotes the fine-tuned determination model at the current moment.

Specifically, the expression of the target return value is as follows:

$${y}_{i} = {R}_{i} + {γmax}_{{a}^{′}} Q ( {S}_{i + 1}^{′} , {a}_{i}^{′} ; {θ}^{′} ) , i = 1 , ... , N$$

where yᵢ denotes a target return value in each state Sᵢ, Rᵢ denotes a reward correspondingly obtained by taking an action a′ᵢ in the state Sᵢ through critic prediction, S′ᵢ₊₁ denotes a state obtained after taking the action a′ᵢ in the state Sᵢ through critic prediction, θ′ denotes a parameter of critic, and max_{a′t}Q(S′ᵢ₊₁, a′ᵢ; θ′) denotes a maximum value in the corresponding state Sᵢ obtained through critic prediction.

Specifically, the expression of calculating corresponding losses based on the target return values is as follows:

$$L ( θ ) = \frac{1}{N} {\sum }_{i = 1}^{N} {( {y}_{i} - Q ( {S}_{i + 1} , {a}_{i} ; θ ) )}^{2}$$

where θ denotes a to-be-updated parameter of actor, Sᵢ₊₁ denotes a state obtained after taking an actual action ai in a state Sᵢ in N samples actually collected in the buffer, and Q(Sᵢ₊₁, aᵢ; θ) denotes an actual value in the state Sᵢ in the N samples actually collected in the buffer.

In order to realize the second purpose of the present invention, the following technical solution is provided: an instability fault monitoring apparatus includes a memory and a processor, the memory has a computer program stored therein, and the processor, when executing the computer program, implements the instability fault monitoring method with self-learning strong generalization capability described above.

The specific implementation process is: a trained model may be deployed to a controller of an actual system, and after the occurrence of instability, electrical features collected by each module are input into the control program to determine the type of the instability fault, so that fault diagnosis and localization of an instability source are carried out.

Compared with the prior art, the present invention has the following beneficial effects:
the core of the model constructed through the present invention is the excellent generalization capability thereof and low requirement for labeled data, so that the model can adapt to and accurately diagnose instability phenomena in various power electronic systems and specific faults of individual modules;
through advanced self-learning algorithms, the method not only can automatically generate high-precision diagnostic models, but also can continuously adapt to the evolution of the systems and different failure modes; and
by utilizing advanced data processing and machine learning techniques, the operational status of the systems can be monitored in real time, and thus potential instability risks can be found in time. The combination of the capability of real-time monitoring and the automatically generated high-precision diagnostic models provides a solid guarantee for the stable operation of the power systems, as well as detailed and accurate guidance for subsequent maintenance and troubleshooting.

### BRIEF DESCRIPTION OF THE DRAWINGS

FIG. 1 is a flowchart of an instability fault monitoring method with self learning strong generalization capability according to the present invention.

FIG. 2 is a composition diagram of actor-critic reinforcement learning architecture according to the present invention.

FIG. 3 is a schematic diagram of training of a deep belief neural network according to the present invention.

FIG. 4 shows a specific flow of training based on actor-critic reinforcement learning architecture and a deep belief neural network according to the present invention.

FIG. 5 is a case of a research object exemplified by the present invention.

### DESCRIPTION OF THE EMBODIMENTS

Exemplary implementations of the present invention are now described with reference to the accompanying drawings, however, the present invention may be implemented in many different forms and is not limited to the embodiments described herein, which are provided for the purpose of disclosing the present invention in an exhaustive and complete manner and of communicating the scope of the present invention adequately to those skilled in the art to which it belongs. Terms used for the exemplary implementations represented in the accompanying drawings are not a limitation of the present invention. In the accompanying drawings, the same units/components use the same reference numerals.

Unless otherwise indicated, terms (including scientific and technical terms) used herein have the commonly understood meaning to those skilled in the art to which they belong. Further, it is to be understood that terms qualified by commonly used dictionaries should be understood to have a meaning consistent with the context of their related fields and should not be understood in an idealized or overly formal sense.

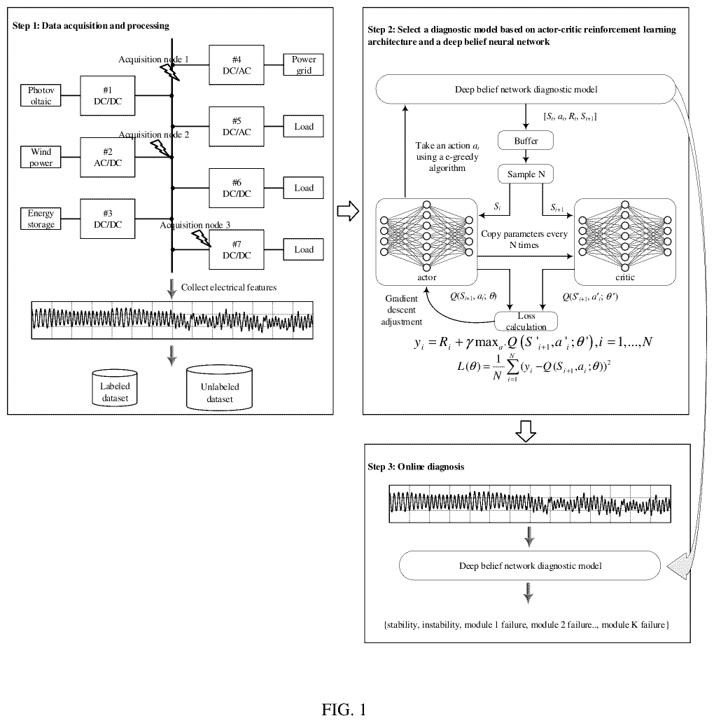

FIG. 1 shows a flowchart of instability fault monitoring according to the present embodiment, which is divided into three steps:
step 1, collect electrical data of each electronic device in a power electronic system, select some of the electrical data to be labeled with types of system instability faults, and combine the labeled electrical data with unlabeled electrical data to form dataset samples;
step 2, construct a classification network based on a deep belief neural network framework, the classification network including a plurality of superimposed and connected network layers and a softmax layer connected to an end network layer, train the classification network using the dataset samples to construct a determination model for determining whether the power electronic system has an instability fault, and
optimize the training process of the classification network using a reinforcement learning algorithm, a reinforcement learning network taking the network layers of different structures as action space, and taking a loss rate of the determination model of previous and latter trainings as an optimization objective to obtain an optimization result, and the optimization result including a superimposed network structure and a corresponding predicted loss rate; and
step 3, input the electrical data in the power electronic system into a determination model satisfying a predetermined predicted loss rate in step 2, so as to output a determination result indicating whether the power electronic system has an instability fault.

Furthermore, the specific process of step S1 includes:
step 1-1, take a bus of the power electronic system as a backbone, and connect power converters in the system to the backbone as module branches, so as to construct an equivalent model of the power electronic system;
step 1-2, collect electrical data from each module branch and the backbone according to a predetermined type of instability faults;
step 1-3, determine the corresponding instability fault category K to be identified, the fault problems to be solved including {stability, instability, module 1 failure, module 2 failure, . . . , module K failure}; and
step 1-4, extract, by a corresponding acquisition node, data to form samples, the data including only a small amount of labeled data and a large amount of unlabeled data.

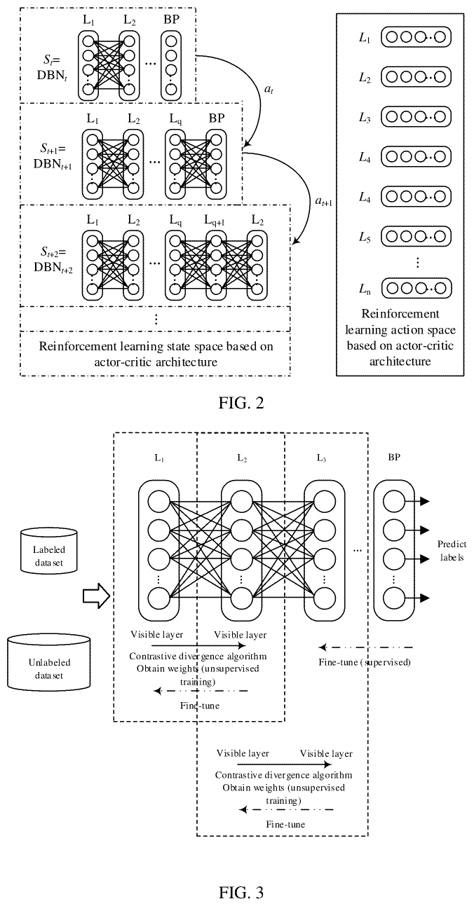

FIG. 2 is a framework diagram of the reinforcement learning algorithm adopted in step 2. The reinforcement learning algorithm is an actor-critic reinforcement learning model. Actor and critic are both multilayer perceptron structures, and the diagnostic model to be constructed is a deep belief neural network including a plurality of superimposed and connected network layers and a softmax layer connected to an end network layer. The network layers are selected from the action space, and the output classification of the softmax layer connected to the end network layer is determined by the category K of a targeted diagnostic task.

The determination model is a deep belief network, which can effectively solve the problem about instability diagnosis in the case of label scarcity. FIG. 3 is a schematic diagram of training of the deep belief neural network. The training process includes an unsupervised pre-training phase and a supervised back-propagation fine-tuning phase.

In the pre-training phase, each of the network layers is trained using a contrastive divergence algorithm based on the dataset samples, so as to construct an initial determination model.

In the back-propagation fine-tuning phase, the constructed initial determination model is fine-tuned based on the labeled electrical data to obtain the determination model for determining whether the power electronic system has an instability fault.

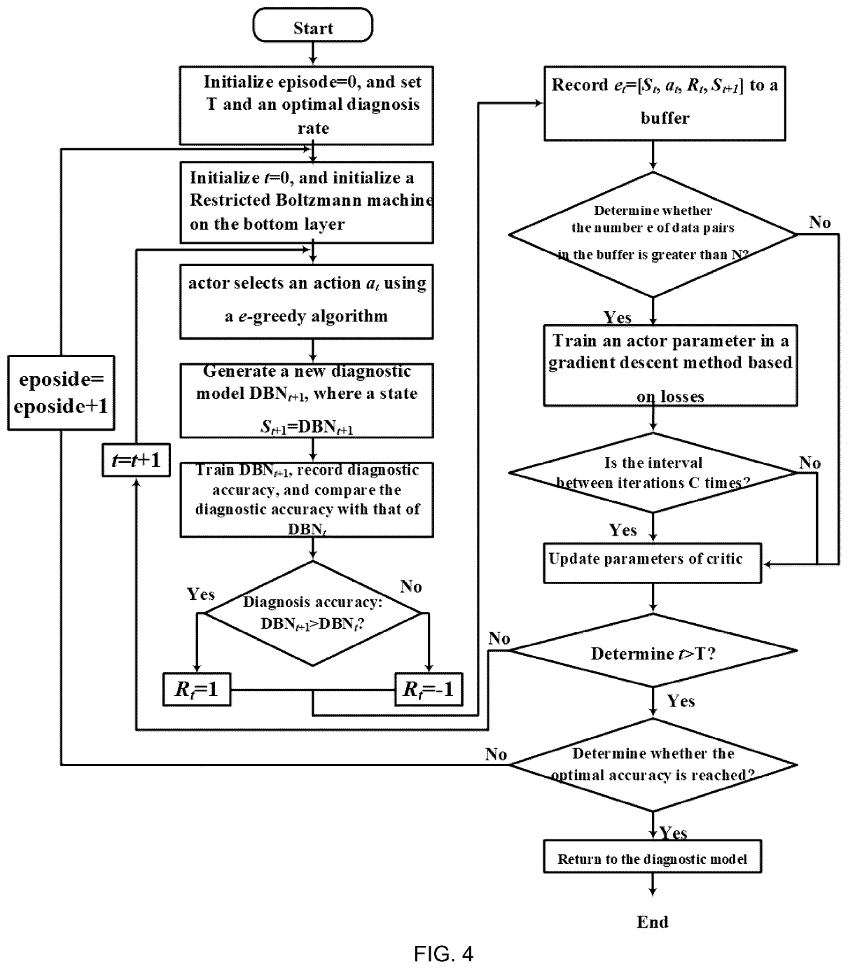

The specific flow of optimizing the classification network using the reinforcement learning algorithm is shown in FIG. 4, including:

parameters are initialized, episode=0, T is set as the maximum number of execution steps in each episode, and the optimal diagnosis rate is set.

Then, the following operations are performed in each episode for a total of T steps:
(1) The iteration moment t=0 is initialized, and an underlying network layer structure is randomly initialized.
(2) Then, actor selects an action aₜ at the current moment using the ε-greedy algorithm, the variation of the parameter ε being obtained using the following equation:

$$ε = \{ \begin{matrix}ε \times {ε}_{Δ} , & if ε \geq {ε}_{min} \\ {ε}_{min} , & others\end{matrix}$$

where εₘᵢₙ denotes the minimum value of ε, and ε_{Δ} is an attenuation factor. The initial ε is set as 1, εₘᵢₙ is 0.1, and ε_{Δ} is 0.998.

The input of actor is a state Sₜ=DBNₜ at the current moment t. Based on the state Sₜ and following the strategy we, actor takes an action aₜ, a network layer is selected from alternative models to form the determination model at the moment t, and then a diagnostic model Sₜ₊₁=DBNₜ₊₁ is formed together with the corresponding softmax layer. It is worth mentioning that the parameter migration technique is adopted, the new diagnostic model does not need to be retrained in the training process, and training is performed after the parameters of Sₜ are directly migrated, which greatly reduces the amount of computation.
(3) The optimal diagnostic accuracy is obtained by comparing the diagnostic accuracy of DBNₜ₊₁ with the diagnostic accuracy of DBNₜ, and at the same time, actor obtains a reward Rₜ according to the following equation:

$${R}_{t} = \{ \begin{matrix}1 & if accuracy : {DBN}_{t + 1} \geq {DBN}_{t} \\ - 1 & if accuracy : {DBN}_{t + 1} < {DBN}_{t}\end{matrix}$$

The obtained eₜ=[Sₜ, aₜ, Rₜ, Sₜ₊₁] is recorded to the buffer.
(4) When the number of data pairs [Sₜ, aₜ, Rₜ, Sₜ₊₁] stored in the buffer reaches a certain set value N (if the number does not reach N, steps (2)-(3) are repeated), training update is performed on the actor parameter. N small batch samples are mainly sampled from the buffer, and critic is utilized to predict the corresponding action a′ᵢ that may be taken in the state Sᵢ (i=1, 2, . . . , N), as well as the obtained reward Rᵢ, and a target return value in the state Sᵢ is calculated.

$${y}_{i} = {R}_{i} + {γmax}_{{a}^{′}} Q ( {S}_{i + 1}^{′} , {a}_{i}^{′} ; {θ}^{′} ) , i = 1 , ... , N$$

where yᵢ denotes a target return value in each state Sᵢ, Rᵢ denotes a reward correspondingly obtained by taking an action a′ᵢ in the state Sᵢ through critic prediction, S′ᵢ₊₁ denotes a state obtained after taking the action a′ᵢ in the state Sᵢ through critic prediction, θ′ denotes a parameter of critic, and max_{a′i}Q(S′ᵢ₊₁, a′ᵢ; θ′) denotes a maximum value in the corresponding state Sᵢ obtained through critic prediction.

A loss function is finally obtained:

$$L ( θ ) = \frac{1}{N} {\sum }_{i = 1}^{N} {( {y}_{i} - Q ( {S}_{i + 1} , {a}_{i} ; θ ) )}^{2}$$

where θ denotes a to-be-updated parameter of actor, Sᵢ₊₁ denotes a state obtained after taking an actual action aᵢ in a state Sᵢ in N samples actually collected in the buffer, and Q(Sᵢ₊₁, aᵢ, θ) denotes an actual value in the state Sᵢ in the N samples actually collected in the buffer.

After the loss is obtained, the actor parameter θ is updated in a gradient descent method.
(5) A weight value of critic is updated every C times to be consistent with a weight value of actor, i.e., θ′=θ.

When the execution exceeds T times, whether the recorded optimal accuracy value meets the requirement is determined. If the value meets the requirement, the training is terminated. Otherwise, the next episode is started, and the neural network of the actor-critic architecture outputs a corresponding diagnostic model.

The present embodiment further provides an instability fault monitoring apparatus. The instability fault monitoring apparatus includes a memory and a processor, the memory has a computer program stored therein, and the processor, when executing the computer program, implements the instability fault monitoring method with self-learning strong generalization capability provided in the above embodiment.

The present invention can automatically generate high-precision diagnostic models for different power electronic system structures and different fault diagnostic tasks, and can continuously adapt to the evolution of the systems and different fault modes. The requirements for data samples are not high, that is, the present invention has practical application values. In addition, by means of advanced data processing and machine learning techniques, the apparatus of the present invention can monitor the operational status of the systems in real time to find potential instability risks in time. The combination of the capability of real-time monitoring and the automatically generated high-precision diagnostic models provides a solid guarantee for the stable operation of the power systems, as well as detailed and accurate guidance for subsequent maintenance and troubleshooting.

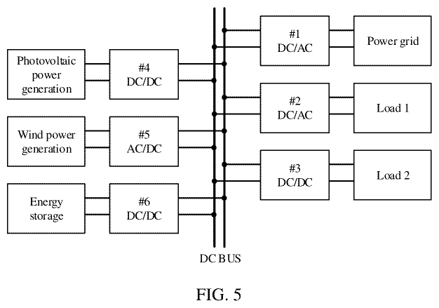

In order to better illustrate the technical effects of the method provided by the present invention, a power electronization power system as shown in FIG. 5 is taken as an example, and an instability fault monitoring and determining network is automatically generated therefor.

In the figure, a DC bus in the system is taken as the backbone, and a photovoltaic power generation module, a wind power generation module, an energy storage module, a power grid, an AC load 1 and a DC load 2 are disposed on two sides of the backbone, each of which is connected to the DC bus through a corresponding power converter.

First, inputs are prepared:

DC bus voltage data in the system is collected, some of the electrical data are selected to be labeled with the types of system instability faults, and the labeled electrical data X_label are combined with unlabeled electrical data X_unlabel to form dataset samples X;
a to-be-determined type K=8 is set, including: {system stability, system instability, module #1 failure, module #2 failure, module #3 failure, module #4 failure, module #5 failure, module #6 failure}; and
then X and the set value K are input into the described instability fault monitoring apparatus for self-learning type strong generalization learning to obtain a generated classification determination model. The specific steps are as follows:
(1) First, the iteration moment t=0 is initialized, and an underlying network layer of the classification determination model is randomly initialized.
(2) Then, the actor structure in reinforcement learning selects an action aₜ at the current moment using the s-greedy algorithm. The input of actor is a state Sᵢ=DBNₜ at the current moment t. Based on the state Sₜ and following the strategy π_{θ}, actor takes the action aₜ, and a network layer is selected from the action space of reinforcement learning, and forms a new classification determination model Sₜ₊₁=DBNₜ₊₁ together with the fixed softmax layer formed by eight nerve cells.
(3) The optimal diagnostic accuracy is obtained by comparing the diagnostic accuracy of DBNₜ₊₁ with the diagnostic accuracy of DBNₜ, and at the same time, actor obtains a reward Rₜ and records the obtained eₜ[Sₜ, aₜ, Rₜ, Sₜ₊₁] to a buffer.
(4) When the number of data pairs [Sₜ, aₜ, Rₜ, Sₜ₊₁] stored in the buffer reaches a certain set value of 20 (if the number does not reach 20, steps (2)-(3) are repeated), training update is performed on the actor parameter at each moment. N small batch samples are mainly sampled from the buffer, and critic is utilized to predict the corresponding action a′ᵢ that may be taken in the state Sᵢ (i=1, 2, . . . , 20), as well as the obtained reward Rᵢ, and a target return value in the state Sᵢ is calculated.

$${y}_{i} = {R}_{i} + {γmax}_{{a}^{′}} Q ( {S}_{i + 1}^{′} , {a}_{i}^{′} ; {θ}^{′} ) , i = 1 , ... , N$$

where yᵢ denotes a target return value in each state Sᵢ, Rᵢ denotes a reward correspondingly obtained by taking an action a′ᵢ in the state Sᵢ through critic prediction, S′ᵢ₊₁ denotes a state obtained after taking the action a′ᵢ in the state Sᵢ through critic prediction, θ′ denotes a parameter of critic, and max_{a′i}Q(S′ᵢ₊₁, a′ᵢ; θ′) denotes a maximum value in the corresponding state Sᵢ obtained through critic prediction.

A loss function is finally obtained:

$$L ( θ ) = \frac{1}{N} {\sum }_{i = 1}^{N} {( {y}_{i} - Q ( {S}_{i + 1} , {a}_{i} ; θ ) )}^{2}$$

where θ denotes a to-be-updated parameter of actor, Sᵢ₊₁ denotes a state obtained after taking an actual action aᵢ in a state Sᵢ in N samples actually collected in the buffer, and Q(Sᵢ₊₁, aᵢ; θ) denotes an actual value in the state Sᵢ in the N samples actually collected in the buffer.

After the loss is obtained, the actor parameter θ is updated in a gradient descent method.
(5) A weight value of critic is updated every 5 times to be consistent with a weight value of actor, i.e., θ′=θ.

Finally, when the recorded optimal accuracy value meets the requirement, the training is terminated, and the neural network of the actor-critic architecture outputs a corresponding diagnostic model.

Finally, the instability monitoring network that can be fully applied to the power electronic system shown in the figure is automatically generated, and the instability monitoring network can automatically output the type of instability faults identified.

1. An instability fault monitoring method with self-learning strong generalization capability, characterized by comprising the following steps:
step 1, collecting electrical data of each electronic device in a power electronic system, selecting some of the electrical data to be labeled with types of system instability faults, and combining the labeled electrical data with unlabeled electrical data to form dataset samples;
step 2, constructing a classification network based on a deep belief neural network framework, the classification network comprising a plurality of superimposed and connected network layers and a softmax layer connected to an end network layer, training the classification network using the dataset samples to construct a determination model for determining whether the power electronic system has an instability fault, and
optimizing the training process of the classification network using a reinforcement learning algorithm, wherein a reinforcement learning network takes a network structure composed of different numbers of network layers and a softmax layer as action space, and takes a loss rate of the determination model of previous and latter trainings as an optimization objective to obtain an optimization result, wherein the optimization result comprises a superimposed network structure and a corresponding predicted loss rate; wherein optimizing the training process comprises:
parameters are initialized, episode=0, T is set as the maximum number of execution steps in each episode, and the optimal diagnosis rate is set; then, the following operations are performed in each episode for a total of T steps:
(1) the iteration moment t=0 is initialized, and an underlying network layer structure is randomly initialized;
(2) then, an actor selects an action aₜ at the current moment using a ε-greedy algorithm;
the input of the actor is a state Sₜ=DBNₜ at the current moment t based on the state Sₜ and following the strategy π_{θ}, the actor takes an action aₜ, a network layer is selected from alternative models to form the determination model at the moment t, and then a diagnostic model Sₜ₊₁=DBNₜ₊₁ is formed together with the corresponding softmax layer;
(3) the optimal diagnostic accuracy is obtained by comparing the diagnostic accuracy of DBNₜ₊₁ with the diagnostic accuracy of DBNₜ, and at the same time, the actor obtains a reward Rₜ;
(4) when the number of data pairs [Sₜ, aₜ, Rₜ, S_{t+1] stored in the buffer reaches a certain set value N (if the number does not reach N, steps (}2)-(3) are repeated), training update is performed on an actor parameter, N small batch samples are mainly sampled from the buffer, and a critic is utilized to predict the corresponding action a′ᵢ that may be taken in the state Sᵢ (i=1, 2, . . . , N), as well as the obtained reward Rᵢ, and a target return value in the state Sᵢ is calculated;
a loss function is finally obtained:
$$L ( θ ) = \frac{1}{N} {\sum }_{i = 1}^{N} {( {y}_{i} - Q ( {S}_{i + 1} , {a}_{i} ; θ ) )}^{2}$$
where θ denotes a to-be-updated parameter of the actor, Sᵢ₊₁ denotes a state obtained after taking an actual action aᵢ in a state Sᵢ in N samples actually collected in the buffer, and Q(Sᵢ₊₁, aᵢ; θ) denotes an actual value in the state Sᵢ in the N samples actually collected in the buffer;
after the loss is obtained, the actor parameter θ is updated in a gradient descent method;
(5) a weight value of the critic is updated every C times to be consistent with a weight value of the actor, i.e., θ′=θ;
when the execution exceeds T times, whether the recorded optimal accuracy value meets the requirement is determined; if the value meets the requirement, the training is terminated; otherwise, the next episode is started, and the neural network of the actor-critic architecture outputs a corresponding diagnostic model;
step 3, inputting the electrical data in the power electronic system into a determination model satisfying a predetermined predicted loss rate in step 2, so as to output a determination result indicating whether the power electronic system has an instability fault.

2. The instability fault monitoring method with self-learning strong generalization capability according to claim 1, characterized in that the specific process of collecting the electrical data is as follows:
taking a bus of the power electronic system as a backbone, and regarding power converters in the power electronic system as module branches to be connected to the backbone, so as to construct an equivalent model of the power electronic system; and
collecting electrical data from each module branch and the backbone according to a predetermined type of instability faults.

3. The instability fault monitoring method with self-learning strong generalization capability according to claim 1, characterized in that the reinforcement learning algorithm is an actor-critic reinforcement learning model.

4. The instability fault monitoring method with self-learning strong generalization capability according to claim 1, characterized in that the training process comprises an unsupervised pre-training phase and a supervised back-propagation fine-tuning phase;
in the pre-training phase, each of the network layers is trained using a contrastive divergence algorithm based on the dataset samples, so as to construct an initial determination model; and
in the back-propagation fine-tuning phase, the constructed initial determination model is fine-tuned based on the labeled electrical data to obtain the determination model for determining whether the power electronic system has an instability fault.

5. The instability fault monitoring method with self-learning strong generalization capability according to claim 4, characterized in that the expression of the reward value is as follows:
$${R}_{t} = \{ \begin{matrix}1 & if accuracy : {DBN}_{t + 1} \geq {DBN}_{t} \\ - 1 & if accuracy : {DBN}_{t + 1} < {DBN}_{t}\end{matrix}$$
wherein DBNₜ₊₁ denotes the determination model at the next moment, and DBNₜ denotes the fine-tuned determination model at the current moment.

6. The instability fault monitoring method with self-learning strong generalization capability according to claim 5, characterized in that the expression of the target return value is as follows:
$${y}_{i} = {R}_{i} + {γmax}_{{a}^{′}} Q ( {S}_{i + 1}^{′} , {a}_{i}^{′} ; {θ}^{′} ) , i = 1 , ... , N$$
wherein yᵢ denotes a target return value in each state Sᵢ, Rᵢ denotes a reward correspondingly obtained by taking an action a′ᵢ in the state Sᵢ through a critic prediction, S′ᵢ₊₁ denotes a state obtained after taking the action a′ᵢ in the state Sᵢ through the critic prediction, θ′ denotes a parameter of the critic, and max_{a′i}Q(S′ᵢ₊₁, a′ᵢ; θ′) denotes a maximum value in the corresponding state Sᵢ obtained through the critic prediction.

7. An instability fault monitoring apparatus, comprising a memory and a processor, and the memory having a computer program stored therein, characterized in that the processor, when executing the computer program, implements the instability fault monitoring method with self-learning strong generalization capability according to claim 1.
